(19) United States
(12) Patent Application Publication
(10) Pub. No.: US 2009/0108474 A1
(43) Pub. Date: Apr. 30, 2009

(54) JUNCTION STRUCTURE AND METHOD OF MANUFACTURING THE SAME

(75) Inventor: Atsuhito Mizutani, Kyoto (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 12/180,758

(22) Filed: Jul. 28, 2008

(30) Foreign Application Priority Data
Oct. 25, 2007 (JP) 2007-277048

(51) Int. Cl. H01L 23/49; H01L 21/60

(52) U.S. Cl. 257/784; 438/617; 257/E23.024; 257/E21.506

(57) ABSTRACT

A junction structure and a method of manufacturing the same are provided which can achieve stable wire bonding between a Poly-Si film bonding pad and an Al wire. The junction structure is made up of a SiO₂ film 5 formed on Si 4, a BPSG film 6 formed on the SiO₂ film 5, a SiN film 7 formed on the BPSG film 6, a Poly-Si film bonding pad 1 formed on the SiN film 7, and an Al wire 2 bonded on the Poly-Si film bonding pad 1. A pad surface average roughness 8 of the Poly-Si film bonding pad 1 can be reduced. Thus it is possible to reduce gaps between bonding surfaces of the Al wire 2 and the Poly-Si film bonding pad 1 and increase a bonding area, thereby improving wire bonding characteristics.

### FIELD OF THE INVENTION

The present invention relates to a junction structure of a Poly-Si film and an Al wire, and a method of manufacturing the same.

### BACKGROUND OF THE INVENTION

In recent years, attention has been given to techniques of micro electro mechanical systems (MEMS) in which electromechanical components are formed by semiconductor micromachining techniques. Developments on MEMS techniques have become active in the fields of machinery, electronics, communications, and medical care.

Generally, in the MEMS techniques, Si is etched with a hydrofluoric acid solution and is processed to a desired shape. In this case, a material etched by a hydrofluoric acid solution as a material of a conducting component cannot be used as a material for obtaining electrical conduction to input/output signals transmitted inside and outside a device. Thus in some techniques, bonding pads are formed by Au or Al to facilitate bonding with Au or Al wires after etching with a hydrofluoric acid solution.

According to Japanese Patent Laid-Open No. 2004-247522 (will be referred to as patent document 1), when Al is used for bonding pads, uneven surfaces on the bonding pads contribute to higher adhesion of members such as bonding wires coming into contact with the pads.

However, when forming Al bonding pads by plating or CVD, a mask is necessary in the step of forming the bonding pads. Further, the number of steps is increased, the manufacturing cost is considerably raised, and the cost of components is increased accordingly.

In order to address this problem, in some methods, bonding pads are formed by a material such as Poly-Si that is not etched by a hydrofluoric acid solution, without forming Al bonding pads. However, in this case, Poly-Si is resistant to plastic deformation unlike Al that is susceptible to plastic deformation as described in patent document 1. Thus as shown in FIG. 5, when a Poly-Si film bonding pad 1 has a considerably uneven surface, gaps 3 are formed on a junction when an Al wire 2 is bonded, so that a sufficient bonding area cannot be obtained and the bonding performance may deteriorate. In FIG. 5, reference numeral 1 denotes the Poly-Si film bonding pad, reference numeral 2 denotes the Al wire, and reference numeral 3 denotes the gaps.

### DISCLOSURE OF THE INVENTION

The present invention is devised to solve the problem. An object of the present invention is to provide a junction structure and a method of manufacturing the same whereby a Poly-Si film bonding pad and an Al wire can be stably wire bonded even when wedge bonding is performed using the Al wire in the junction structure having the Poly-Si film bonding pad.

In order to attain the object, a junction structure of the present invention includes: a SiO₂ film formed on Si; one of a BPSG film and a PSG film formed on the SiO₂ film; a SiN film formed on one of the BPSG film and the PSG film; a Poly-Si film formed on the SiN film; and an Al wire bonded on the Poly-Si film.

Further, in the aforementioned configuration, the Poly-Si film has a surface average roughness not larger than the surface roughness of one of the BPSG film and the PSG film.

Moreover, in the aforementioned configuration, the Poly-Si film has a surface roughness not larger than 22 nm.

Further, in the aforementioned configuration, the Poly-Si film has a thickness not smaller than 200 nm.

A method of manufacturing the junction structure of the present invention includes the steps of: forming a SiO₂ film on Si; forming one of a BPSG film and a PSG film on the SiO₂ film; forming a SiN film on one of the BPSG film and the PSG film; forming a Poly-Si film on the SiN film; and bonding an Al wire on the Poly-Si film.

The junction structure and the method of manufacturing the same according to the present invention do not require a process of forming Al or Au on the Poly-Si film acting as a bonding pad, so that the manufacturing period can be shorter than the manufacturing period of the prior art and a mask for the process can be eliminated. Thus it is possible to manufacture the junction structure of the Poly-Si film and the Al wire with an inexpensive manufacturing process. Further, the present invention can reduce the surface average roughness of the Poly-Si film. Thus gaps between bonding surfaces of the Al wire and the Poly-Si film are reduced and the bonding area is increased, thereby improving wire bonding characteristics.

### BRIEF DESCRIPTION OF THE DRAWINGS

FIG. 1 is a sectional view showing a junction structure according to an embodiment of the present invention;

FIG. 2 is an enlarged view showing the surface of a Poly-Si film bonding pad of the junction structure;

FIG. 3 is an enlarged view showing a junction between the Poly-Si film bonding pad and an Al wire of the junction structure;

FIG. 4 shows wire pull test results on a Poly-Si film and the Al wire; and

FIG. 5 is a sectional view showing a junction structure of the prior art.

### DESCRIPTION OF THE EMBODIMENTS

A junction structure and a method of manufacturing the same according to an embodiment of the present invention will be described below in accordance with the accompanying drawings.

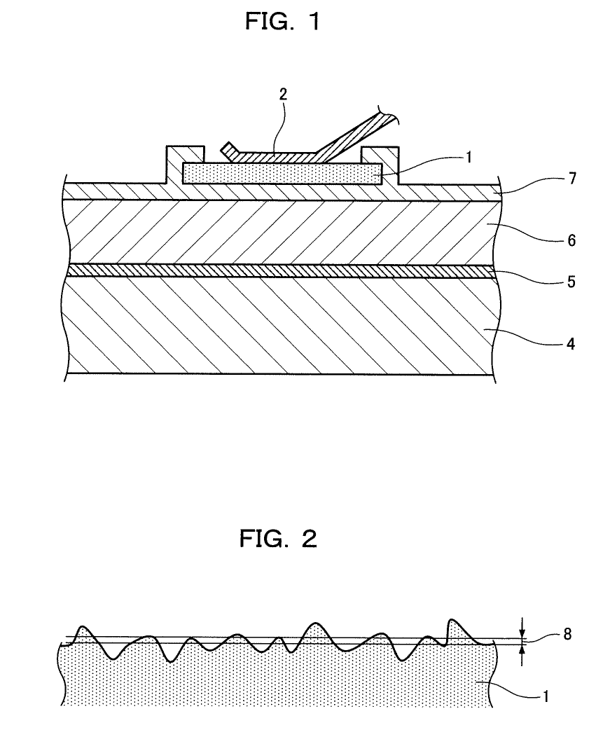

FIGS. 1 and 2 are a sectional view showing the junction structure according to the embodiment of the present invention, and an enlarged view of the surface of a Poly-Si film bonding pad.

As shown in FIG. 1, in the junction structure according to the embodiment of the present invention, a SiO₂ film 5 is formed on Si 4, a BPSG film 6 is formed on the SiO₂ film 5, a SiN film 7 is formed on the BPSG film 6, a Poly-Si film bonding pad 1 is formed on the SiN film 7, and an Al wire 2 is bonded on the Poly-Si film bonding pad 1. In FIG. 2, reference numeral 8 denotes a pad surface average roughness.

The junction structure is manufactured as follows:

The SiO₂ film 5 is formed on the Si 4 in an atmosphere of oxygen at 1000° C. to 1200° C., and the SiO₂ film 5 is reacted by atmospheric pressure CVD in an atmosphere containing SiH₄, O₂, PH₃, and B₂H₆ gas at 350° C. to 450° C., so that the BPSG film 6 is formed on the SiO₂ film 5. Next, the BPSG film 6 is heat treated at 850° C. to 950° C. and is reacted by low pressure CVD in an atmosphere containing SiH₂Cl₂ and NH₃ gas at 700° C. to 800° C., so that the SiN film 7 is formed on the BPSG film 6. Further, the SiN film 7 is reacted by low pressure CVD in an atmosphere containing SiH₄ gas at 600° C. to 700° C., so that the Poly-Si film bonding pad 1 is formed on the SiN film 7. At this moment, the pad surface average roughness 8 (see FIG. 2) of the Poly-Si film bonding pad 1 is not larger than the surface roughness of the BPSG film 6. By controlling the surface roughness of the BPSG film 6 thus, the pad surface average roughness 8 of the Poly-Si film bonding pad 1 can be reduced.

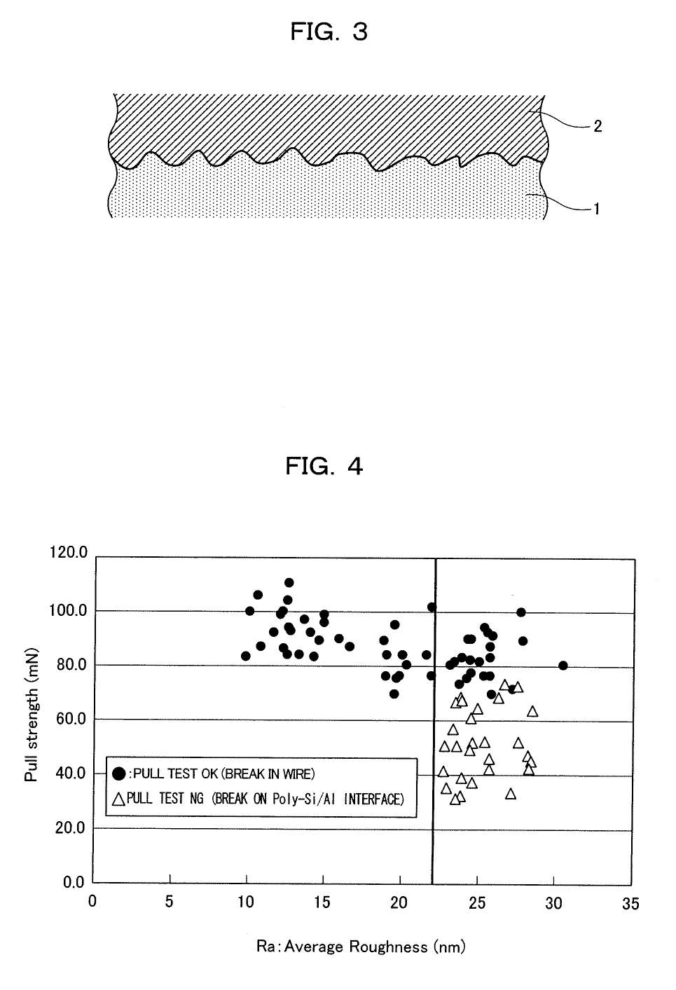

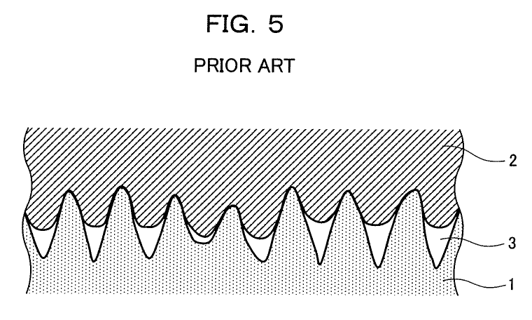

FIG. 3 is an enlarged view of a junction between the Poly-Si film bonding pad 1 and the Al wire 2 of FIG. 1. When bonding the Al wire 2 to the Poly-Si film bonding pad 1, a state of the surface of the Poly-Si film bonding pad 1 predominantly affects the plastic deformation of the Al wire 2. In other words, when the Poly-Si film bonding pad 1 has a rough surface, deformation of the Al wire 2 increases gaps 3 between bonding surfaces, resulting in an insufficient bonding strength. By reducing the pad surface average roughness 8 of the Poly-Si film bonding pad 1, the gaps 3 between the bonding surfaces are reduced and thus the bonding area of the Poly-Si film bonding pad 1 and the Al wire 2 is increased when the Al wire 2 is bonded to the Poly-Si film bonding pad 1. Thus it is possible to prevent wire bonding characteristics from deteriorating.

FIG. 4 is a graph showing the relationship between the pad surface average roughness 8 of the Poly-Si film bonding pad 1 and a pull strength obtained when a pull test (tensile test) is conducted after the Poly-Si film bonding pad 1 and the Al wire 2 are wire bonded. According to the experimental results of FIG. 4, in a wire pull test conducted on the junction structure of the Poly-Si film bonding pad 1 and the Al wire 2, when the pad surface average roughness 8 of the Poly-Si film bonding pad 1 is larger than 22 nm, a break occurs on the bonding interface of the Poly-Si film bonding pad 1 and the Al wire 2 and the pull strength decreases. When the pad surface average roughness 8 of the Poly-Si film bonding pad 1 is not larger than 22 nm, a break occurs in the Al wire 2 and a stable pull strength is obtained. As is evident from the results of the pull test, it is considered that bonding between the Poly-Si film bonding pad 1 and the Al wire 2 can be stabilized by reducing the pad surface average roughness 8 of the Poly-Si film bonding pad 1.

When the BPSG film 6 is formed by atmospheric pressure CVD, the surface roughness of the BPSG film 6 is controlled by performing heat treatment at 850° C. to 950° C. with concentration B of 1 wt % or more and concentration P of 5.9 wt % or more, so that the pad surface average roughness 8 of the Poly-Si film bonding pad 1 can be 22 nm or lower. Thus it is possible to stabilize wire bonding characteristics between the Poly-Si film bonding pad 1 and the Al wire 2.

By setting the thickness of the Poly-Si film bonding pad 1 at 200 nm or more, it is possible to prevent a stress applied to the Poly-Si film bonding pad 1 during wire bonding from causing a brittle fracture on a Poly-Si film, and thus stabilize wire bonding without causing exfoliation of the Poly-Si film bonding pad 1.

Further, the aforementioned configuration does not require a process of forming Al or Au on the Poly-Si film bonding pad 1, so that the manufacturing period can be shorter than the manufacturing period of the prior art and a mask for the process can be eliminated. Thus it is possible to provide a junction structure which can stably wire bond the Poly-Si film bonding pad 1 and the Al wire 2 with an inexpensive manufacturing process.

The BPSG film 6 may be an interlayer insulating film such as a PSG film.

What is claimed is:

1. A junction structure comprising:
a SiO₂ film formed on Si;
one of a BPSG film and a PSG film formed on the SiO₂ film;
a SiN film formed on one of the BPSG film and the PSG film;
a Poly-Si film formed on the SiN film; and
an Al wire bonded on the Poly-Si film.

2. The junction structure according to claim 1, wherein the Poly-Si film has a surface average roughness not larger than a surface roughness of one of the BPSG film and the PSG film.

3. The junction structure according to claim 1, wherein the Poly-Si film has a surface roughness not larger than 22 nm.

4. The junction structure according to claim 1, wherein the Poly-Si film has a thickness not smaller than 200 nm.

5. A method of manufacturing a junction structure, comprising the steps of:
forming a SiO₂ film on Si;
forming one of a BPSG film and a PSG film on the SiO₂ film;
forming a SiN film on one of the BPSG film and the PSG film;
forming a Poly-Si film on the SiN film; and
bonding an Al wire on the Poly-Si film.
